(19) United States
(12) Patent Application Publication
(10) Pub. No.: US 2009/0108321 A1
(43) Pub. Date: Apr. 30, 2009

(54) FLASH MEMORY

(75) Inventors: Ming-Cheng Chang, Taipei County (TW); Wei-Ming Liao, Taipei City (TW); Jer-Chyi Wang, Taoyuan County (TW); Chien-Chang Huang, Taipei City (TW)

Correspondence Address: QUINTERO LAW OFFICE, PC, 2210 MAIN STREET, SUITE 200, SANTA MONICA, CA, 90405, US

(73) Assignee: NANYA TECHNOLOGY CORPORATION, TAOYUAN (TW)

(21) Appl. No.: 11/948,947

(22) Filed: Nov. 30, 2007

(30) Foreign Application Priority Data
Oct. 30, 2007 (TW) TW96140741

(51) Int. Cl. H01L 29/788

(52) U.S. Cl. 257/314; 257/E29.3

(57) ABSTRACT

A flash memory is provided. The flash memory includes a substrate, a first insulation layer formed on the substrate, a control gate disposed on the first insulation layer, and two floating gates coplanar with the substrate respectively disposed on both sides of the control gate.

### BACKGROUND OF THE INVENTION

1. Field of the Invention

The invention relates to a memory device, and in particular to a flash memory having two floating gates.

2. Description of the Related Art

One type of non-volatile semiconductor memory device is an erasable programmable read-only memory (EPROM), and one form of an EPROM is a flash memory. Generally, a flash memory cell comprises two gates (one floating gate and one control gate), wherein the floating gate stores charges and the control gate controls data input and output. The floating gate is conventionally disposed underneath the control gate, without connection to external circuits. The control gate is conventionally connected to the word line. The flash memory can rapidly erase entire memory areas within about 1-2 sec. Recently, flash memory is widely used in various consumer electronic products, for example, digital cameras, digital video devices, mobile phones, portable computers, or walkmans.

In an effort to increase operating speed of an integrated circuit chip, shrinkage of memory cell size and reduction of power consumption are required for high-density semiconductor device fabrication. For a conventional planar transistor, a gate length must be shortened to reduce lateral area when fabricating a small-sized memory unit. However, when the gate length is shortened to about 45 nm or less, it becomes difficult to shorten the dielectric layer underneath the floating gate. Additionally, short channel effect or hot carrier effect may easily occur with device size reduction, which leads to the result of reducing device reliability.

### BRIEF SUMMARY OF THE INVENTION

One embodiment of the invention provides a flash memory comprising a substrate, a first insulation layer formed on the substrate, a control gate disposed on the first insulation layer, and two floating gates coplanar with the substrate respectively disposed on either sides of the control gate.

One embodiment of the invention provides a flash memory having two floating gates. The two floating gates are respectively disposed on respective side of the control gate in the memory unit. Both floating gates are controlled by the control gate such that two sets of data can simultaneously be input and output, effectively improving device performance. Additionally, short channel effect and hot carrier effect resulting from size reduction can be overcome due to the increase of floating gate number compensating for the decrease in gate size.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawing, wherein:

FIG. 1 shows an arrangement of a flash memory device according to an embodiment of the invention.

FIG. 2 is a cross-sectional view of a flash memory device structure according to an embodiment of the invention, along cross-sectional line A-A in FIG. 1.

FIGS. 3A-3C show a method of fabricating a flash memory device according to an embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

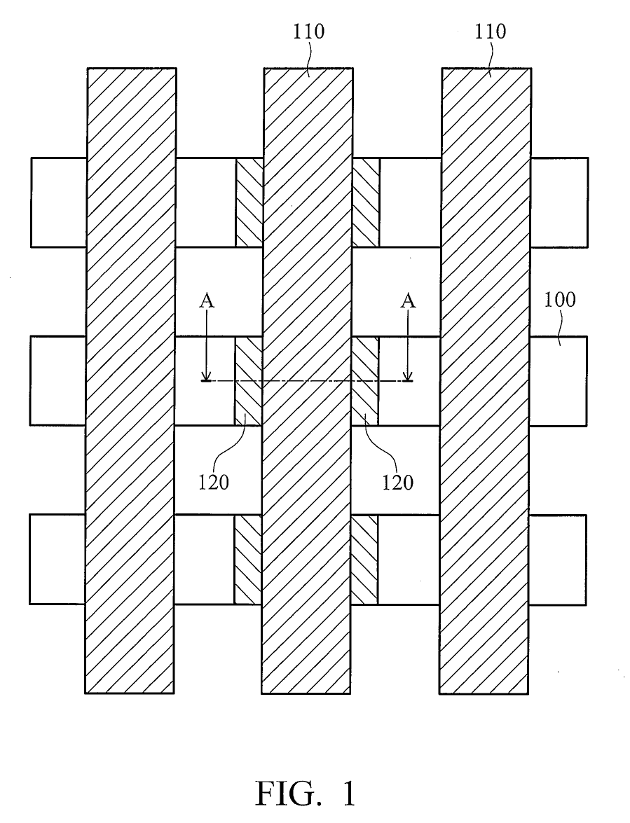

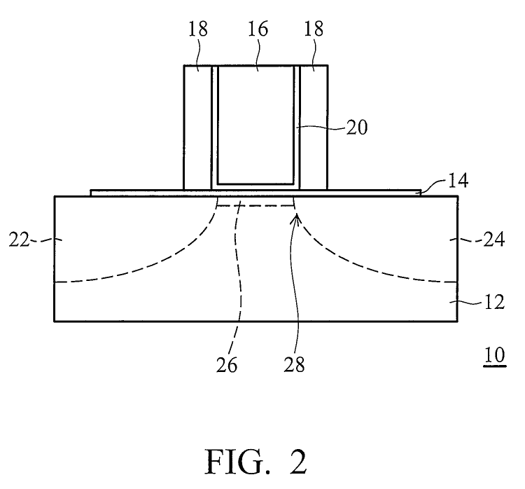

Referring to FIGS. 1 and 2, a flash memory device is provided in an embodiment of the invention. FIG. 1 shows an arrangement of the flash memory device. FIG. 2 is a partial cross-sectional view along cross-sectional line A-A in FIG. 1.

In FIG. 1, sign 100 represents an active area, sign 110 represents a gate layer, and sign 120 represents floating gates at either side of the gate layer 110.

In FIG. 2, a flash memory 10 comprises a substrate 12, a first insulation layer 14, a control gate 16, two floating gates 18, and a second insulation layer 20. The first insulation layer 14 is formed on the substrate 12. The control gate 16 is disposed on the first insulation layer 14. Two floating gates 18 are disposed on two opposed sides of the control gate 16, respectively coplanar with the substrate 12. The second insulation layer 20 is formed between the control gate 16 and the first insulation layer 14 and between the control gate 16 and the two floating gates 18.

The substrate 12 may be a p-type or n-type silicon substrate. The first insulation layer 14 may be an oxide layer. The control gate 16 may comprise polysilicon. The floating gate 18 may comprise high-k materials, for example, nitride or oxide. Nitride may comprise silicon nitride. Oxide may comprise metal oxide, for example, hafnium oxide, zirconium oxide, or aluminum oxide. The second insulation layer 20 may also be an oxide layer.

The flash memory 10 further comprises a source 22 and a drain 24 formed in the substrate 12, respectively at two opposed sides of the control gate 16. A channel 26 is further formed in the substrate 12 between the source 22 and the drain 24. Additionally, a p-n junction 28, for example, a graded junction, is further formed at a junction between the channel 26 and the source/drain (22/24), with an altered concentration ranging from 1×10¹⁹ to 1×10¹⁷/20 μm.

Compared to conventional flash memory having one control gate and one floating gate, the invention provides a flash memory having two floating gates. There are two floating gates respectively disposed on two opposed sides of control gate in the memory unit. Both floating gates are controlled by the control gate such that two sets of data can simultaneously be input and output, effectively improving device performance. Additionally, short channel effect and hot carrier effect resulting from reduced size can be overcome due to the increase in floating gate number compensating for the decrease in gate size.

When electrons are collected by the floating gate, the electrons are positioned upright, resulting in an increased threshold voltage. Similar to other erasable programmable read-only memories (EPROM), a high electric field is then applied between the floating gate and source or substrate to remove the electrons from the floating gate, and facilitate electron tunneling to the source or the substrate through the oxide layer.

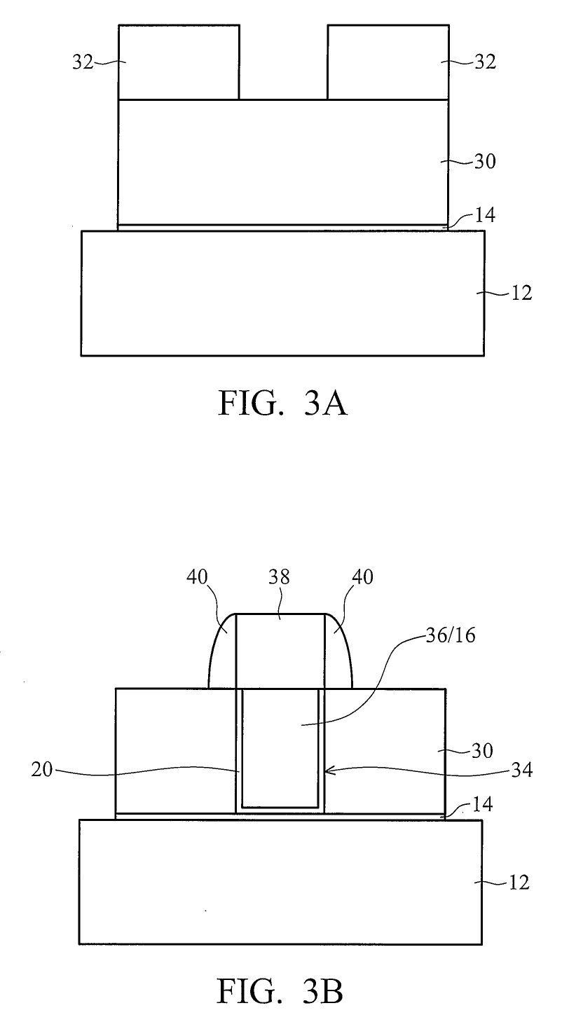

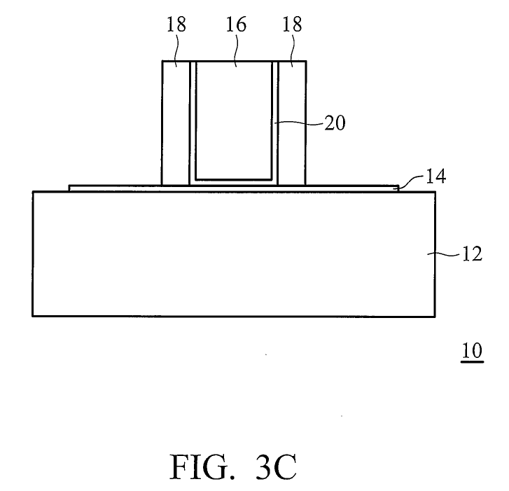

FIGS 3A-3C disclose a method of fabricating a flash memory device in an embodiment of the invention. Referring to FIG. 3A, a substrate 12 is provided. An oxide layer (the first insulation layer) 14 and an aluminum oxide layer 30 are formed on the substrate 12 in order. A patterned nitride layer 32 is then formed on the aluminum oxide layer 30.

Next, the aluminum oxide layer 30 is etched using the patterned nitride layer 32 as a mask until the oxide layer 14 is exposed to define a trench 34, as shown in FIG. 3B. After the patterned nitride layer 32 is removed, an oxide layer (the second insulation layer) 20 is conformally formed on the surface of the aluminum oxide layer 30 (not shown) and the side wall and bottom of the trench 34. A polysilicon layer 36 is then formed on the oxide layer 20 (not shown) and filled into the trench 34. Next, the oxide layer 20 and the polysilicon layer 36 on top of the aluminum oxide layer 30 are removed by, for example, chemical mechanical polish (CMP) to form a control gate 16 in the trench 34. Another patterned nitride layer 38 is then formed on the polysilicon layer 36. Spacers 40 are formed on two opposed sides of the patterned nitride layer 38.

Next, the aluminum oxide layer 30 is etched using the patterned nitride layer 38 and the spacers 40 as masks to define two floating gates 18, as shown in FIG. 3C. Thus, completing the flash memory 10 having two floating gates 18. In addition to the foregoing method, the flash memory provided by the invention can be fabricated by any proper semiconductor processes.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

1. A flash memory, comprising:
a substrate;
a first insulation layer formed on the substrate;
two floating gates formed on the first insulation layer and each having an inner side wall respectively opposite to each other;
a second insulation layer formed on the first insulation layer and completely covering the inner side wall of each of the two floating gates; and
a control gate formed on the second insulation layer and between the two floating gates such that the control gate is sandwiched by the second insulation layer.

2-20. (canceled)
